(19) United States
(12) Patent Application Publication
(10) Pub. No.: US 2025/0155410 A1
(43) Pub. Date: May 15, 2025

(54) POWER ELECTRONIC DEVICE DEGRADATION MONITORING APPARATUS AND METHOD

(71) Applicant: HUNAN UNIVERSITY, Changsha City (CN)

(72) Inventors: Yunze HE, Changsha City (CN); Xuefeng GENG, Changsha City (CN); Jie ZHANG, Changsha City (CN); Longhai TANG, Changsha City (CN); Shan CHANG, Changsha City (CN)

(21) Appl. No.: 18/816,368

(22) Filed: Aug. 27, 2024

(30) Foreign Application Priority Data
Nov. 10, 2023 (CN) 202311498014.6

(51) Int. Cl. G01N 29/14; G01N 29/22

(52) U.S. Cl. CPC G01N 29/14; G01N 29/227; G01N 2291/0289

(57) ABSTRACT

Provided are a power electronic device degradation monitoring apparatus and method. The apparatus includes a power cycling test system, a heat sink, an acoustic emission sensor, a power electronic device under test, and a signal processing system. The acoustic emission sensor is configured to collect a stress wave signal released by the power electronic device under test at each turn-off time and transmitted by the heat sink. The signal processing system is configured to preprocess the stress wave signal collected by the acoustic emission sensor, extract feature components from a preprocessed stress wave signal, calculate key feature parameters of each feature component, and compare the calculated key feature parameters with key feature parameters of the power electronic device under test in a healthy status to obtain a degradation status of the power electronic device under test.

### CROSS REFERENCE TO RELATED APPLICATION

This patent application claims the benefit and priority of Chinese Patent Application No. 202311498014.6, filed with the China National Intellectual Property Administration on Nov. 10, 2023, the disclosure of which is incorporated by reference herein in its entirety as part of the present application.

### TECHNICAL FIELD

The present disclosure relates to the technical field of power electronic device health status evaluation, and in particular, to a power electronic device degradation monitoring apparatus and method.

### BACKGROUND

A health status of a power electronic device is very important to ensure reliable operation of a power electronic system. Reliability of power electronic devices needs to be verified before mass production, and a power cycling test is an important content to evaluate reliability of device packaging.

During the power cycling test, a degree of packaging degradation of a device is usually represented by monitoring electrical parameters (such as saturation voltage drop) and thermal parameters (such as steady-state thermal resistance) of the device. On the one hand, monitoring the electrical parameters and the thermal parameters of the device requires the support from a complex peripheral circuit, which may lead to the decline of system stability and increase a failure rate of the system, and lead to limited monitoring accuracy of the device status. On the other hand, control algorithms are complex, and the monitoring of the electrical parameters and the thermal parameters needs to involve accurate and complex control algorithms to ensure accuracy and stability of monitoring data.

Research shows that power electronic devices may release stress wave signals that can be measured by an acoustic emission sensor at a switching time (see literature: Karkkainen T J, Talvitie J P, Kuisma M et al. Acoustic Emission in Power Semiconductor Modules—First Observations[J]. IEEE Transactions on Power Electronics, 2014, 29 (11): 6081-6086). These stress wave signals contain information that can reflect a health status of devices. However, there is little research work on applying stress waves released by power electronic devices to degradation monitoring of the devices during a power cycling test. An acoustic emission monitoring technology features nondestructiveness, real time, accuracy, simplicity, and convenience, and thus it is of great significance to apply the acoustic emission monitoring technology to the power cycling test of power electronic devices to monitor a health status of the power electronic devices.

Bejger A et al (see literature: Bejger A, Kozak M, Gordon R. The use of acoustic emission elastic waves as diagnosis method for insulated-gate bipolar transistor[J]. Journal of Marine Engineering&Technology, Taylor&Francis, 2020, 19 (4): 186-196.) have compared stress waves released by a healthy power electronic device and a faulty power electronic device at a switching time. Results indicate significant differences in power spectra of the power electronic devices, but no specific measurement method is provided, and quantitative representation of a device degradation status is not achieved by means of stress wave characteristics. Choe C et al (see literature: Choe C, Chen C, Nagao S, et al. Real-Time Acoustic Emission Monitoring of Wear-Out Failure in SiC Power Electronic Devices During Power Cycling Tests[J]. IEEE Transactions on Power Electronics, 2021, 36 (4): 4420-4428.) have used stress wave released by a power electronic device to represent a device packaging degradation degree, but a sensor for measuring the stress waves is directly attached to a power chip. This measurement method is complicated to operate and too high in cost, and a temperature rise of the power electronic device during a power cycling test may affect sensitivity of an acoustic emission sensor, which is not conducive to practical application.

The temperature of the power electronic device would change to generate electromagnetic interference during the power cycling test. This is not conducive to direct measurement, by a contact acoustic emission sensor, of stress waves released by the device. In addition, stress waves released by the power electronic device in different health statuses are different, and how to extract effective features to represent a health status of the device is also a key technology to apply the acoustic emission monitoring technology to power electronic device degradation monitoring.

### SUMMARY

An objective of the present disclosure is to provide a power electronic device degradation monitoring apparatus and method, to solve the problem that when an acoustic emission sensor is directly attached to a surface of a power electronic device to test stress wave signals, sensitivity of the sensor is affected by a change in temperature of the device, which leads to inaccurate testing.

The present disclosure solves the above technical problems by means of the following technical solutions: A power electronic device degradation monitoring apparatus includes a power cycling test system, a heat sink, an acoustic emission sensor, a power electronic device under test, and a signal processing system, where the acoustic emission sensor and the power electronic device under test are both arranged on the heat sink;
the power cycling test system is configured to perform a power cycling test on the power electronic device under test;
the heat sink is configured to dissipate heat from the power electronic device under test and transmit a stress wave signal released by the power electronic device under test at each turn-off time to the acoustic emission sensor during the power cycling test;
the acoustic emission sensor is configured to collect the stress wave signal released by the power electronic device under test at each turn-off time and transmitted by the heat sink; and
the signal processing system is configured to preprocess the stress wave signal collected by the acoustic emission sensor, extract feature components from a preprocessed stress wave signal, calculate key feature parameters of each feature component, and compare the calculated key feature parameters with key feature parameters of the power electronic device under test in a healthy status to obtain a degradation status of the power electronic device under test.

Further, the power cycling test system includes a power supply unit, an electronic load, and a control unit; the power supply unit is configured to provide a supply voltage to the power electronic device under test; the control unit is configured to control a switching state of the power electronic device under test; and the electronic load is configured to serve as a load of the power electronic device under test during the power cycling test.

Further, the key feature parameters include an amplitude and a peak-to-peak value of a time domain component of the stress wave signal in a frequency band of 100 kHz to 150 kHz, and signal energy of a time domain component of the stress wave signal in a frequency band of 150 kHz to 250 kHz.

Further, the signal processing system includes a preprocessing unit, a feature extraction unit, and a calculation and comparison unit;
the preprocessing unit is configured to preprocess the stress wave signal collected by the acoustic emission sensor;
the feature extraction unit is configured to extract feature components from a preprocessed stress wave signal, and the feature components include a time domain component in a frequency band of 100 kHz to 150 kHz and a time domain component in a frequency band of 150 kHz to 250 kHz; and
the calculation and comparison unit is configured to calculate key feature parameters of each feature component, and compare the calculated key feature parameters with key feature parameters of the power electronic device under test in a healthy status to obtain a degradation status of the power electronic device under test.

Further, the preprocessing unit includes a low-pass filter and an amplifier module; and the low-pass filter is configured to filter out high-frequency noise in the stress wave signal, and the amplifier module is configured to amplify the stress wave signal.

Further, the feature extraction unit includes a first band pass filter and a second band pass filter;
the first band pass filter is configured to extract the time domain component in the frequency band of 100 kHz to 150 kHz from the preprocessed stress wave signal; and
the second band pass filter is configured to extract the time domain component in the frequency band of 150 kHz to 250 kHz from the preprocessed stress wave signal.

Further, the signal processing system is further configured to obtain a gate drive turn-off signal of the power electronic device under test, and control, based on the gate drive turn-off signal, the acoustic emission sensor to collect the stress wave signal released by the power electronic device under test at each turn-off time.

Based on the same concept, the present disclosure further provides a power electronic device degradation status monitoring method. Based on the power electronic device degradation monitoring apparatus described above, the monitoring method includes the following steps:
step 1: obtaining key feature parameters of a power electronic device under test in a healthy status;
step 2: performing a power cycling test on the power electronic device under test;
step 3: collecting, during the power cycling test, a stress wave signal released by the power electronic device under test at a current turn-off time;
step 4: preprocessing the stress wave signal;
step 5: extracting feature components from a preprocessed stress wave signal;
step 6: calculating key feature parameters of each feature component;
step 7: comparing the calculated key feature parameters with the key feature parameters of the power electronic device under test in the healthy status to obtain a degradation status of the power electronic device under test; and
step 8: collecting a stress wave signal released by the power electronic device under test at a next turn-off time, and proceeding to step 4 until the power cycling test is completed.

### Beneficial Effects

Compared with the prior art, the present disclosure has the following advantages:

According to the present disclosure, a power electronic device and an acoustic emission sensor are both arranged on a heat sink, so that an impact of a temperature on sensitivity of the acoustic emission sensor is reduced, and more minor faults and anomalies can be detected. In addition, an interference signal is suppressed by means of a time difference generated in transmitting a stress wave signal to the acoustic emission sensor, which improves quality and accuracy of the stress wave signal collected by the acoustic emission sensor. According to the present disclosure, an acoustic emission technology is adopted, so that there is no need for any physical interference or disassembly of the power electronic device, which implements non-invasive detection and reduces the complexity of maintenance and operation.

According to the present disclosure, feature components are extracted from the stress wave signal, and key feature parameters of each feature component are calculated, which can more accurately represent a degradation status of the power electronic device and improve accuracy of degradation status monitoring.

According to the present disclosure, without complicated debugging or devices, the monitoring apparatus is easy to deploy and maintain, which simplifies a monitoring operation process and reduces the possibility of operational errors, thus improving usability and friendliness of the monitoring apparatus.

### BRIEF DESCRIPTION OF THE DRAWINGS

In order to describe the technical solutions of the present disclosure more clearly, the accompanying drawings required to describe the embodiments are briefly described below. Apparently, the accompanying drawings described below show only one embodiment of the present disclosure. Those of ordinary skill in the art may further obtain other accompanying drawings based on these accompanying drawings without creative efforts.

FIG. 1 is a schematic diagram of a power electronic device degradation monitoring apparatus according to an embodiment of the present disclosure;

FIG. 2 is a diagram showing a circuit principle of a band pass filter in an embodiment of the present disclosure;

FIGS. 3A-3B are a collector-emitter current ice and a stress wave signal u_{AE} collected by an acoustic emission sensor in an embodiment of the present disclosure;

FIG. 4 is a diagram showing a normalized trend of saturation voltage drop Vₛₐₜ, junction-to-case thermal resistance R_{jc} and junction-heat sink steady-state thermal resistance Rⱼₕ of a power electronic device in an embodiment of the present disclosure with a number of cycles;

FIG. 5A is a diagram showing a normalized trend of key feature parameters of time domain components of stress wave signals in a frequency band of 20 kHz to 100 kHz in the case of different numbers of cycles in an embodiment of the present disclosure;

FIG. 5B is a diagram showing a normalized trend of key feature parameters of time domain components of stress wave signals in a frequency band of 100 kHz to 150 kHz in the case of different numbers of cycles in an embodiment of the present disclosure;

FIG. 5C is a diagram showing a normalized trend of key feature parameters of time domain components of stress wave signals in a frequency band of 150 kHz to 250 kHz in the case of different numbers of cycles in an embodiment of the present disclosure;

FIG. 5D is a diagram showing a normalized trend of key feature parameters of time domain components of stress wave signals in a frequency band of 250 kHz to 500 kHz in the case of different numbers of cycles in an embodiment of the present disclosure; and

FIG. 6 is a flowchart of a power electronic device degradation status monitoring method according to an embodiment of the present disclosure.

Description of reference signs: 1—Power electronic device under test, 2—Acoustic emission sensor, 3—Amplifier module, 4—Upper computer.

### DETAILED DESCRIPTION OF THE EMBODIMENTS

The technical solutions in the present disclosure are clearly and completely described below with reference to the accompanying drawings in the embodiments of the present disclosure. Apparently, the described embodiments are merely some rather than all of the embodiments of the present disclosure. All other embodiments obtained by those of ordinary skill in the art based on the embodiments of the present disclosure without creative efforts shall fall within the protection scope of the present disclosure.

The technical solutions of the present application are described in detail below with reference to specific embodiments. The following specific embodiments may be combined with each other, and the same or similar concepts or processes may not be repeatedly described in some embodiments.

### Embodiment 1

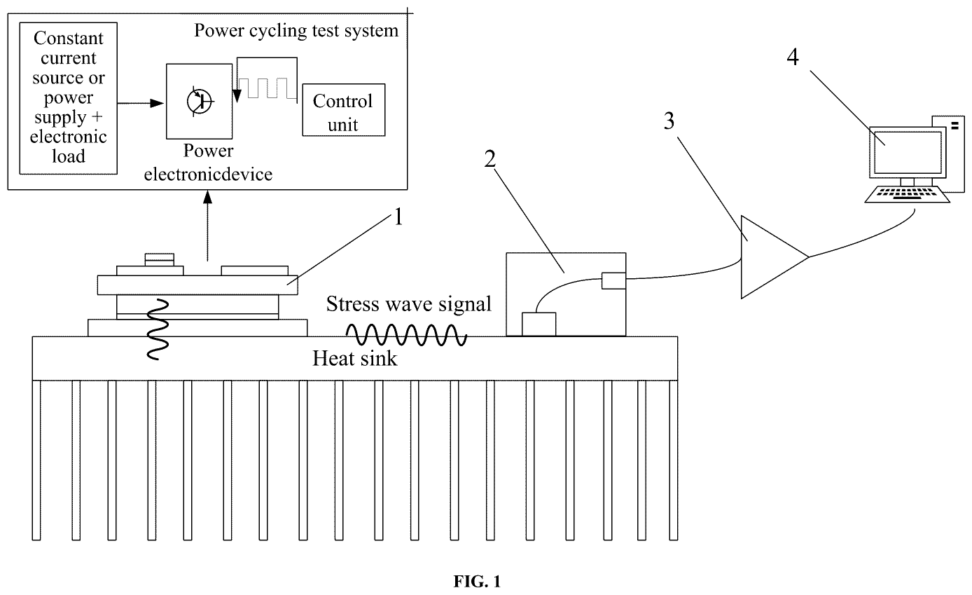

As shown in FIG. 1, a power electronic device degradation monitoring apparatus according to the embodiment of the present disclosure includes a power cycling test system, a heat sink, an acoustic emission sensor 2, a power electronic device under test 1 (namely insulated gate bipolar transistor (IGBT)), and a signal processing system. The acoustic emission sensor 2 and the power electronic device under test 1 are both arranged on the heat sink. The power electronic device under test 1 is connected to the power cycling test system, and the acoustic emission sensor 2 is connected to the signal processing system.

The power cycling test system is configured to perform a power cycling test on the power electronic device under test 1. In a specific implementation of the present disclosure, the power cycling test system includes a power supply unit, an electronic load, and a control unit. The power supply unit is configured to provide a supply voltage to the power electronic device under test 1. The control unit is configured to provide a driving signal to control a switching state of the power electronic device under test 1. The electronic load is configured to serve as a load of the power electronic device under test 1 during the power cycling test, to obtain a load current. In this embodiment, the power supply unit is a direct current power supply, or the power supply unit and the electronic load may be directly replaced by a constant current source, which directly supplies a load current.

The acoustic emission sensor 2 and the power electronic device under test 1 are both arranged on the heat sink. The power electronic device under test 1 is spaced apart from the tested emission sensor 2 by a certain distance (for example, the power electronic device under test 1 and the acoustic emission sensor 2 are at two ends of the heat sink), and a stress wave signal released by the power electronic device under test 1 at a turn-off time is transmitted to the acoustic emission sensor 2 by means of the heat sink. Therefore, the heat sink not only dissipates heat from the power electronic device under test 1, thus avoiding an impact of a temperature on sensitivity of the acoustic emission sensor 2, but also transmits a stress wave signal released by the power electronic device under test 1 at each turn-off time to the acoustic emission sensor 2 during the power cycling test. Due to the different transmission speeds of electromagnetic interference and sound waves in a medium, a transmission delay of the stress wave signal avoids an impact of an electromagnetic interference signal and improves quality and accuracy of the stress wave signal collected by the acoustic emission sensor 2.

Acoustic emission detection is a non-destructive testing method, and is used to monitor tiny sounds or sound waves inside an object. The acoustic emission sensor 2 collects a stress wave signal released by the power electronic device under test 1 at each turn-off time and transmitted by the heat sink, and processes and analyzes the stress wave signal, so as to evaluate potential tiny faults inside the device. An oscilloscope or an upper computer 4 is used to capture a gate drive turn-off signal of the power electronic device under test 1, and the acoustic emission sensor 2 is controlled based on the gate drive turn-off signal to collect the stress wave signal released by the power electronic device under test 1 at each turn-off time.

The signal processing system is configured to preprocess the stress wave signal collected by the acoustic emission sensor 2, extract feature components from a preprocessed stress wave signal, calculate key feature parameters of each feature component, and compare the calculated key feature parameters with key feature parameters of the power electronic device under test 1 in a healthy status to obtain a degradation status of the power electronic device under test 1.

In a specific implementation of the present disclosure, the signal processing system includes a preprocessing unit, a feature extraction unit, and a calculation and comparison unit. The preprocessing unit is configured to preprocess the stress wave signal collected by the acoustic emission sensor 2. The feature extraction unit is configured to extract feature components from a preprocessed stress wave signal, and the feature components include a time domain component in a frequency band of 100 kHz to 150 kHz and a time domain component in a frequency band of 150 kHz to 250 kHz. The calculation and comparison unit is configured to calculate key feature parameters of each feature component, and compare the calculated key feature parameters with key feature parameters of the power electronic device under test 1 in a healthy status to obtain a degradation status of the power electronic device under test 1.

In this embodiment, the preprocessing unit includes a low-pass filter and an amplifier module 3; and the low-pass filter is configured to filter out high-frequency noise in the stress wave signal, and the amplifier module 3 is configured to amplify the stress wave signal.

In this embodiment, the feature extraction unit includes a first band pass filter and a second band pass filter. The first band pass filter is configured to extract the time domain component in the frequency band of 100 kHz to 150 kHz from the preprocessed stress wave signal; and the second band pass filter is configured to extract the time domain component in the frequency band of 150 kHz to 250 kHz from the preprocessed stress wave signal.

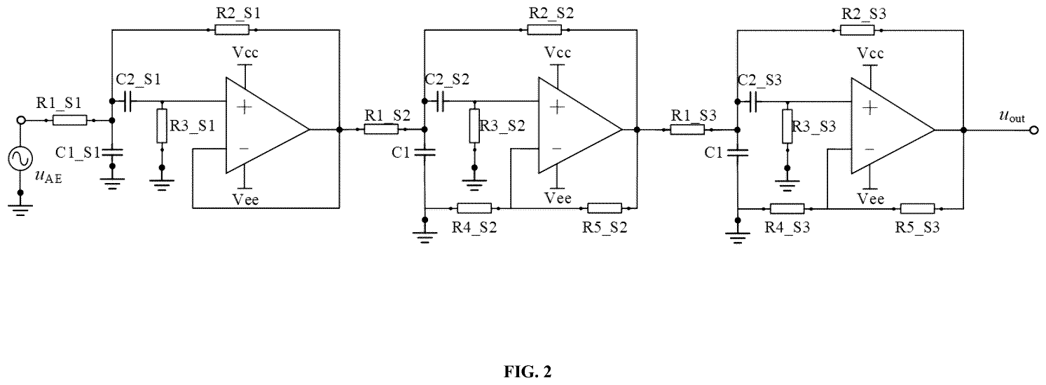

FIG. 2 is a diagram showing a circuit principle of a band pass filter. The band pass filter includes three-stage amplifiers connected in sequence. When different parameters are selected for resistance and capacitance in the band pass filter, time domain components in different frequency bands are extracted. In this embodiment, when C1_S1=100 pf, C1_S2=100 pf, C1_S3=100 pf, C2_S1=100 pf, C2_S2=100 pf, C2_S3=100 pf, R1_S1=8.06 kΩ, R1_S2=31.6 kΩ, R1_S3=5.9 kΩ, R2_S1=232Ω, R2_S2=35.7 kΩ, R2_S3=6.65 kΩ, R3_S1=1.13 MΩ, R3_S2=78.7 kΩ, R3_S3=15.4 kΩ, R4_S2=2.8 kΩ, R4_S3=2.8 kΩ, R5_S2=2.49 kΩ, and R5_S3=2.49 kΩ, the band pass filter in FIG. 2 is the first band pass filter, and time domain components in the frequency band of 100 kHz to 150 kHz can be extracted from a preprocessed stress wave signal u_{AE}. When C1_S1=100 pf, C1_S2=100 pf, C1_S3=100 pf, C2_S1=100 pf, C2_S2=100 pf, C2_S3=100 pf, R1_S1=4.75 kΩ, R1_S2=22.1 kΩ, R1_S3=3.57 kΩ, R2_S1=150Ω, R2_S2=28.7 kΩ, R2_S3=4.64 kΩ, R3_S1=768 kΩ, R3_S2=56.2 kΩ, R3_S3=9.09 kΩ, R4_S2=2.49 kΩ, R4_S3=2.49 kΩ, R5_S2=4.49 kΩ, and R5_S3=2.49 kΩ, the band pass filter in FIG. 2 is the second band pass filter, and time domain components in the frequency band of 150 kHz to 250 kHz can be extracted from the preprocessed stress wave signal u_{AE}.

In another specific implementation of the present disclosure, the feature extraction unit is implemented by means of software, with a specific implementation process as follows: using signal processing software (such as Matlab) to design a digital band pass filter, and extracting time domain components in the frequency band of 100 kHz to 150 kHz and time domain components in the frequency band of 150 kHz to 250 kHz from the preprocessed stress wave signal u_{AE} by means of the digital band pass filter designed by the software.

In this embodiment, the upper computer 4 is adopted as the calculation and comparison unit, and the upper computer 4 may further display a stress wave waveform, or the oscilloscope may be used to display the stress wave waveform.

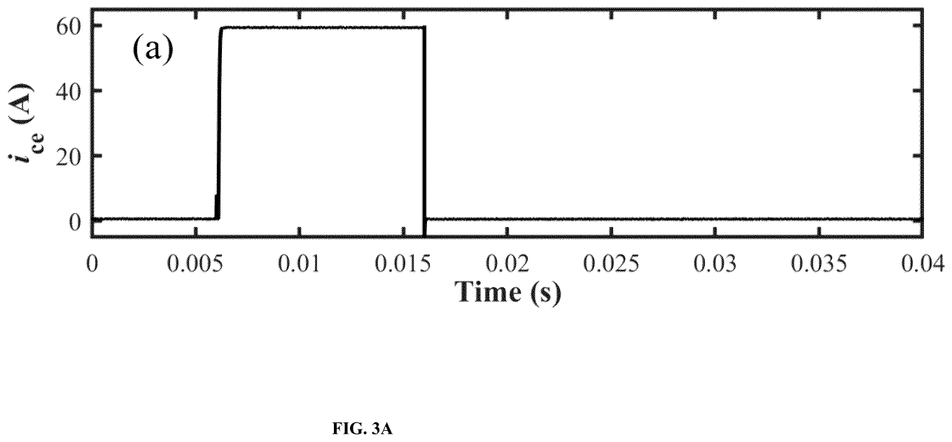

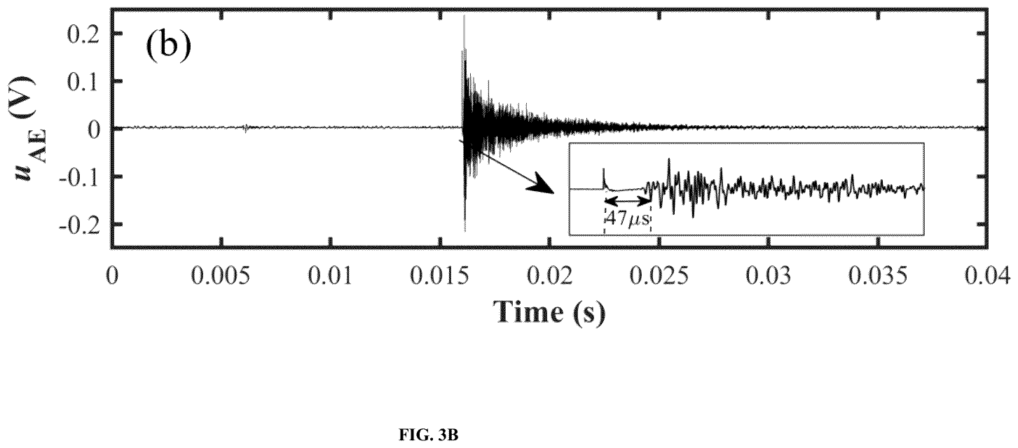

During the power cycling test, when a heating stage of the power electronic device ends and a heat dissipation stage begins (that is, at a turn-off time of the power electronic device), a collector-emitter current ice of the power electronic device and a stress wave signal u_{AE} received by the acoustic emission sensor 2 at the turn-off time are shown in FIGS. 3A-3B. As can be seen from FIGS. 3A-3B, the power electronic device can release a stress wave at the turn-off time, and the measured stress wave signal can decouple the electromagnetic interference signal by means of a transmission delay difference, so as to obtain a real stress wave signal from the power electronic device. This indicates that when the acoustic emission sensor 2 is mounted on the heat sink, the real stress wave signal released by the device at the turn-off time can be extracted by means of the signal transmission delay difference. In addition, this is also beneficial to decoupling the impact of the temperature on the sensitivity of the acoustic emission sensor 2. Since the power electronic device is at a certain distance from the acoustic emission sensor 2, a temperature rise of the power electronic device basically does not affect the sensitivity of the acoustic emission sensor 2.

Frequency bands of the stress wave signal include 20 kHz to 100 kHz, 100 kHz to 150 kHz, 150 kHz to 250 kHz, and 250 kHz to 500 kHz. In the present disclosure, only the time domain components of 100 kHz to 150 kHz and 150 kHz to 250 kHz are extracted as feature components by means of the band pass filter, and the key feature parameters include an amplitude and a peak-to-peak value of a time domain component of the stress wave signal in a frequency band of 100 kHz to 150 kHz, and signal energy of a time domain component of the stress wave signal in a frequency band of 150 kHz to 250 kHz, which can more accurately characterize a degradation status of the power electronic device and improve accuracy of degradation status monitoring.

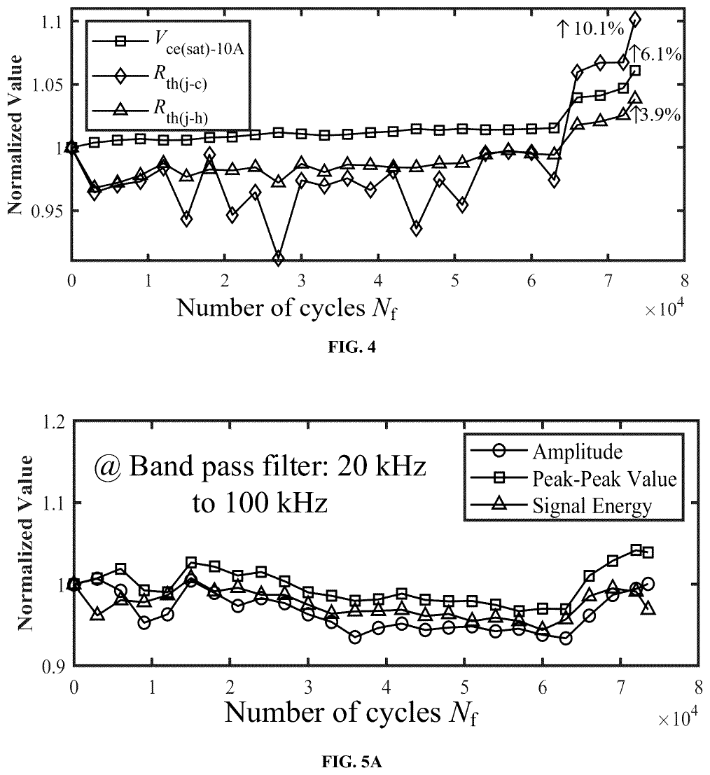

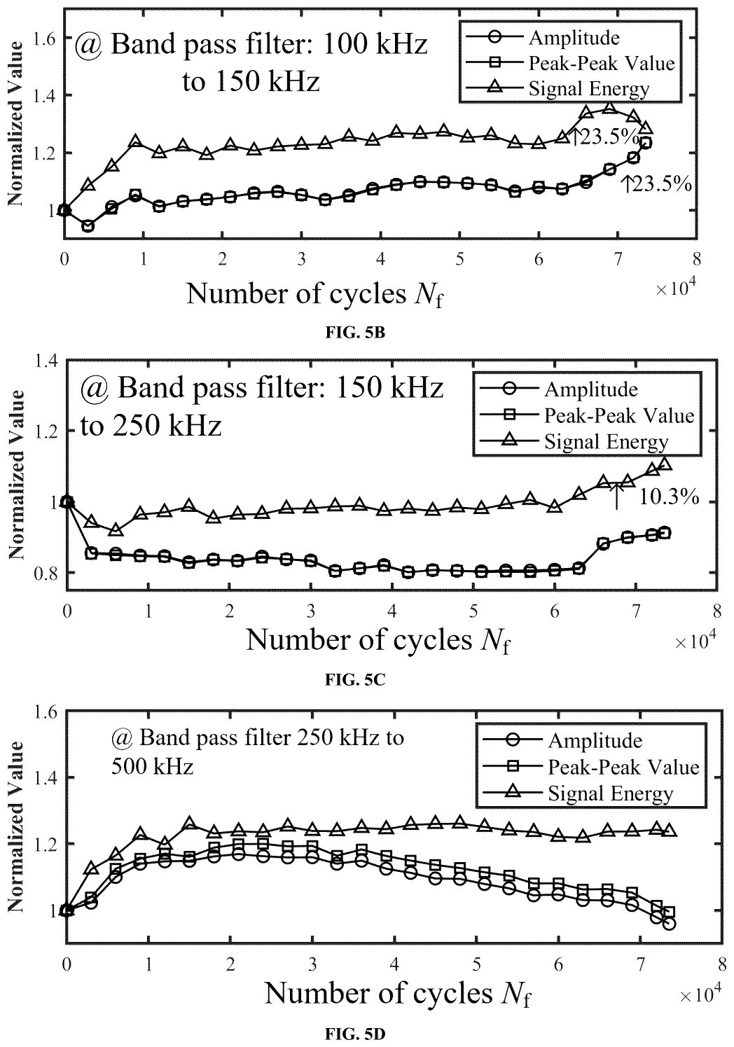

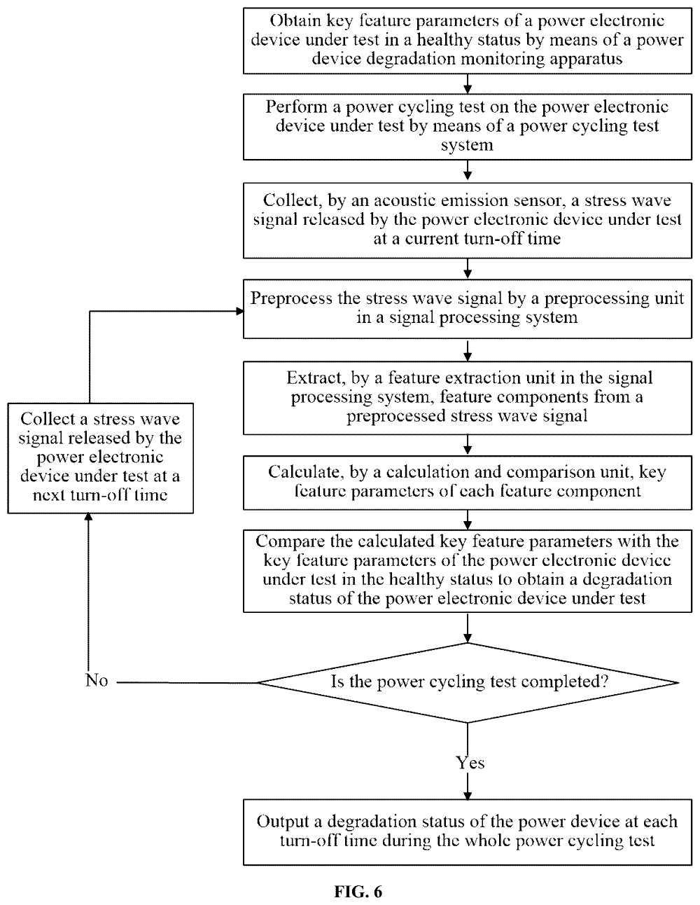

In order to prove the advantages of the key feature parameters of the present disclosure, conventional degradation monitoring parameters of the power electronic device (including saturation voltage drop Vₛₐₜ, junction-to-case thermal resistance R_{jc} and junction-heat sink steady-state thermal resistance Rⱼₕ of the power electronic device, as shown in FIG. 4) and time domain components of turn-off stress wave signals of the power electronic device during degradation (as shown in FIGS. 5(a) to 5(d)) were simultaneously extracted. As can be seen from FIGS. 5(a) to 5(d), an amplitude and a peak-to-peak value of a time domain component of a stress wave in the frequency band of 100 kHz to 150 kHz and signal energy of a time domain component in the frequency band of 150 kHz to 250 kHz during degradation gradually increased with the degradation. By comparison between FIG. 4 and FIGS. 5(a) to 5(d), it can be found that Vₛₐₜ, R_{jc} and Rⱼₕ of the power electronic device changed by 6.1%, 10.1% and 3.9% respectively with the degradation. During the power cycling test of the power electronic device, the amplitude and the peak-to-peak value of the time domain component of the stress wave signal released by the power electronic device at each turn-off time in the frequency band of 100 kHz to 150 kHz changed by more than 20%, and the changes were more obvious. The signal energy of the time domain component of the stress wave signal released by the power electronic device at each turn-off time in the frequency band of 150 kHz to 250 kHz also showed a gradual increase trend, and the amplitude increased by more than 10%. Therefore, the key feature parameters of time domain components in the frequency bands of 100 kHz to 150 kHz and 150 kHz to 250 kHz have obvious advantages compared with those of a conventional electrical parameter method and thermal parameter method, and there is no complicated measuring circuit. This is very beneficial to the application of the acoustic emission monitoring technology in power electronic device degradation monitoring.

### Embodiment 2

As shown in FIG. 6, based on the power electronic device degradation monitoring apparatus according to Embodiment 1, the embodiment of the present disclosure provides a power electronic device degradation status monitoring method, including the following steps.
Step 1: Obtain key feature parameters of a power electronic device under test in a healthy status by means of a power electronic device degradation monitoring apparatus.
Step 2: Perform a power cycling test on the power electronic device under test by means of a power cycling test system.
step 3: During the power cycling test, collect, by an acoustic emission sensor, a stress wave signal released by the power electronic device under test at a current turn-off time.
Step 4: Preprocess, by a preprocessing unit in a signal processing system, the stress wave signal.
Step 5: Extract, by a feature extraction unit in the signal processing system, feature components from a preprocessed stress wave signal, where the feature components include a time domain component in a frequency band of 100 kHz to 150 kHz and a time domain component in a frequency band of 150 kHz to 250 kHz.
Step 6: Calculate, by a calculation and comparison unit, key feature parameters of each feature component, that is, calculate an amplitude and a peak-to-peak value of the time domain component in the frequency band of 100 kHz to 150 kHz, and signal energy of the time domain component in the frequency band of 150 kHz to 250 kHz.
step 7: Compare the calculated key feature parameters with the key feature parameters of the power electronic device under test in the healthy status to obtain a degradation status of the power electronic device under test.
step 8: Collect a stress wave signal released by the power electronic device under test at a next turn-off time, and proceed to step 4 until the power cycling test is completed.

Before the power cycling test is performed on the power electronic device, the power electronic device degradation monitoring apparatus according to Embodiment 1 is first used to measure the key feature parameters of the power electronic device, that is, the amplitude and the peak-to-peak value of the time domain component of the stress wave signal released by the power electronic device at the turn-off time in the frequency band of 100 kHz to 150 kHz, and the signal energy of the time domain component in the frequency band of 150 kHz to 250 kHz. Since no power cycling test has been performed on the power electronic device, the key feature parameters measured before the power cycling test are used as key feature parameters of the power electronic device in a healthy status.

In step 7, the amplitude and the peak-to-peak value of the time domain component in the frequency band of 100 kHz to 150 kHz at each turn-off time are compared with the amplitude and the peak-to-peak value in the frequency band of 100 kHz to 150 kHz in a healthy status respectively, and the signal energy of the time domain component in the frequency band of 150 kHz to 250 kHz at each turn-off time is compared with the signal energy of the time domain component in the frequency band of 150 kHz to 250 kHz in a healthy status, to obtain a degradation status of the power electronic device at the turn-off time, and then a degradation status of the power electronic device at each turn-off time during the whole power cycling test is obtained. After the power cycling test is completed, a degradation status report of the power electronic device can be generated, and whether there is a fault, a time of occurrence and a severity of the fault during the power cycling test can be analyzed based on the degradation status report.

The above disclosed are merely specific implementations of the present disclosure, and the protection scope of the present disclosure is not limited thereto. Any change or modification easily conceived by those skilled in the art within the technical scope of the present disclosure should fall within the protection scope of the present disclosure.

What is claimed is:

1. A power electronic device degradation monitoring apparatus, comprising a power cycling test system, a heat sink, an acoustic emission sensor, a power electronic device under test, and a signal processing system, wherein the acoustic emission sensor and the power electronic device under test are both arranged on the heat sink;
the power cycling test system is configured to perform a power cycling test on the power electronic device under test;
the heat sink is configured to dissipate heat from the power electronic device under test and transmit a stress wave signal released by the power electronic device under test at each turn-off time to the acoustic emission sensor during the power cycling test;
the acoustic emission sensor is configured to collect the stress wave signal released by the power electronic device under test at each turn-off time and transmitted by the heat sink; and
the signal processing system is configured to preprocess the stress wave signal collected by the acoustic emission sensor, extract feature components from a preprocessed stress wave signal, calculate key feature parameters of each feature component, and compare the calculated key feature parameters with key feature parameters of the power electronic device under test in a healthy status to obtain a degradation status of the power electronic device under test.

2. The power electronic device degradation monitoring apparatus according to claim 1, wherein the power cycling test system comprises a power supply unit, an electronic load, and a control unit; the power supply unit is configured to provide a supply voltage to the power electronic device under test; the control unit is configured to control a switching state of the power electronic device under test; and the electronic load is configured to serve as a load of the power electronic device under test during the power cycling test.

3. The power electronic device degradation monitoring apparatus according to claim 1, wherein the key feature parameters comprise an amplitude and a peak-to-peak value of a time domain component of the stress wave signal in a frequency band of 100 kHz to 150 kHz, and signal energy of a time domain component of the stress wave signal in a frequency band of 150 kHz to 250 kHz.

4. The power electronic device degradation monitoring apparatus according to claim 1, wherein the signal processing system comprises a preprocessing unit, a feature extraction unit, and a calculation and comparison unit;
the preprocessing unit is configured to preprocess the stress wave signal collected by the acoustic emission sensor;
the feature extraction unit is configured to extract feature components from a preprocessed stress wave signal, and the feature components comprise a time domain component in a frequency band of 100 kHz to 150 kHz and a time domain component in a frequency band of 150 kHz to 250 kHz; and
the calculation and comparison unit is configured to calculate key feature parameters of each feature component, and compare the calculated key feature parameters with key feature parameters of the power electronic device under test in a healthy status to obtain a degradation status of the power electronic device under test.

5. The power electronic device degradation monitoring apparatus according to claim 4, wherein the preprocessing unit comprises a low-pass filter and an amplifier module; and the low-pass filter is configured to filter out high-frequency noise in the stress wave signal, and the amplifier module is configured to amplify the stress wave signal.

6. The power electronic device degradation monitoring apparatus according to claim 4, wherein the feature extraction unit comprises a first band pass filter and a second band pass filter;
the first band pass filter is configured to extract the time domain component in the frequency band of 100 kHz to 150 kHz from the preprocessed stress wave signal; and
the second band pass filter is configured to extract the time domain component in the frequency band of 150 kHz to 250 kHz from the preprocessed stress wave signal.

7. The power electronic device degradation monitoring apparatus according to claim 1, wherein the signal processing system is further configured to obtain a gate drive turn-off signal of the power electronic device under test, and control, based on the gate drive turn-off signal, the acoustic emission sensor to collect the stress wave signal released by the power electronic device under test at each turn-off time.

8. A power electronic device degradation status monitoring method, wherein the monitoring method is based on the power electronic device degradation monitoring apparatus according to claim 1, and specifically comprises the following steps:
step 1: obtaining key feature parameters of a power electronic device under test in a healthy status;
step 2: performing a power cycling test on the power electronic device under test;
step 3: collecting, during the power cycling test, a stress wave signal released by the power electronic device under test at a current turn-off time;
step 4: preprocessing the stress wave signal;
step 5: extracting feature components from a preprocessed stress wave signal;
step 6: calculating key feature parameters of each feature component;
step 7: comparing the calculated key feature parameters with the key feature parameters of the power electronic device under test in the healthy status to obtain a degradation status of the power electronic device under test; and
step 8: collecting a stress wave signal released by the power electronic device under test at a next turn-off time, and proceeding to step 4 until the power cycling test is completed.

9. The power electronic device degradation monitoring apparatus according to claim 2, wherein the signal processing system is further configured to obtain a gate drive turn-off signal of the power electronic device under test, and control, based on the gate drive turn-off signal, the acoustic emission sensor to collect the stress wave signal released by the power electronic device under test at each turn-off time.

10. The power electronic device degradation monitoring apparatus according to claim 3, wherein the signal processing system is further configured to obtain a gate drive turn-off signal of the power electronic device under test, and control, based on the gate drive turn-off signal, the acoustic emission sensor to collect the stress wave signal released by the power electronic device under test at each turn-off time.

11. The power electronic device degradation monitoring apparatus according to claim 4, wherein the signal processing system is further configured to obtain a gate drive turn-off signal of the power electronic device under test, and control, based on the gate drive turn-off signal, the acoustic emission sensor to collect the stress wave signal released by the power electronic device under test at each turn-off time.

12. The power electronic device degradation monitoring apparatus according to claim 5, wherein the signal processing system is further configured to obtain a gate drive turn-off signal of the power electronic device under test, and control, based on the gate drive turn-off signal, the acoustic emission sensor to collect the stress wave signal released by the power electronic device under test at each turn-off time.

13. The power electronic device degradation monitoring apparatus according to claim 6, wherein the signal processing system is further configured to obtain a gate drive turn-off signal of the power electronic device under test, and control, based on the gate drive turn-off signal, the acoustic emission sensor to collect the stress wave signal released by the power electronic device under test at each turn-off time.

14. The power electronic device degradation status monitoring method according to claim 8, wherein the power cycling test system comprises a power supply unit, an electronic load, and a control unit; the power supply unit is configured to provide a supply voltage to the power electronic device under test; the control unit is configured to control a switching state of the power electronic device under test; and the electronic load is configured to serve as a load of the power electronic device under test during the power cycling test.

15. The power electronic device degradation status monitoring method according to claim 8, wherein the key feature parameters comprise an amplitude and a peak-to-peak value of a time domain component of the stress wave signal in a frequency band of 100 kHz to 150 kHz, and signal energy of a time domain component of the stress wave signal in a frequency band of 150 kHz to 250 kHz.

16. The power electronic device degradation status monitoring method according to claim 8, wherein the signal processing system comprises a preprocessing unit, a feature extraction unit, and a calculation and comparison unit;
the preprocessing unit is configured to preprocess the stress wave signal collected by the acoustic emission sensor;
the feature extraction unit is configured to extract feature components from a preprocessed stress wave signal, and the feature components comprise a time domain component in a frequency band of 100 kHz to 150 kHz and a time domain component in a frequency band of 150 kHz to 250 kHz; and
the calculation and comparison unit is configured to calculate key feature parameters of each feature component, and compare the calculated key feature parameters with key feature parameters of the power electronic device under test in a healthy status to obtain a degradation status of the power electronic device under test.

17. The power electronic device degradation status monitoring method according to claim 16, wherein the preprocessing unit comprises a low-pass filter and an amplifier module; and the low-pass filter is configured to filter out high-frequency noise in the stress wave signal, and the amplifier module is configured to amplify the stress wave signal.

18. The power electronic device degradation status monitoring method according to claim 16, wherein the feature extraction unit comprises a first band pass filter and a second band pass filter;
the first band pass filter is configured to extract the time domain component in the frequency band of 100 kHz to 150 kHz from the preprocessed stress wave signal; and
the second band pass filter is configured to extract the time domain component in the frequency band of 150 kHz to 250 kHz from the preprocessed stress wave signal.

19. The power electronic device degradation status monitoring method according to claim 8, wherein the signal processing system is further configured to obtain a gate drive turn-off signal of the power electronic device under test, and control, based on the gate drive turn-off signal, the acoustic emission sensor to collect the stress wave signal released by the power electronic device under test at each turn-off time.
